(19) United States
(12) Patent Application Publication
(10) Pub. No.: US 2004/0207059 A1
(43) Pub. Date: Oct. 21, 2004

(54) Package structure with a cavity

(76) Inventor: Chu Wan Hong, Gang-Shan (TW)

Correspondence Address: LOWE HAUPTMAN GILMAN & BERNER, LLP, Suite 310, 1700 Diagonal Road, Alexandria, VA, 22314, US

(21) Appl. No.: 10/813,062

(22) Filed: Mar. 31, 2004

(30) Foreign Application Priority Data
Apr. 17, 2003 (TW) 092109184

(51) Int. Cl. H01L 23/02

(52) U.S. Cl. 257/678

(57) ABSTRACT

A package structure with a cavity comprises a chip, a multi-layer ceramic substrate, and an adhesive layer. The chip has a circuit disposed thereon and a plurality of first bonding pads disposed around the circuit, and the multi-layer ceramic substrate has a cave formed thereon and a plurality of second bonding pads disposed around the cave wherein the cave and the plurality of second bonding pads are corresponding to the circuit and the plurality of first bonding pads, respectively. The adhesive layer is applied to the surface of the substrate, with the cave and the second pads exposed from the adhesive layer, for tightly bonding the chip and the multi-layer ceramic substrate together such that the circuit of the chip is corresponding to the cave of the multi-layer ceramic substrate so as to form a cavity.

### BACKGROUND OF THE INVENTION

1. Field of the Invention

This invention generally relates to a multi-layer ceramic (MLC) package structure, and more particularly to a low-temperature co-fired ceramic (LTCC) package structure with a cavity.

2. Description of the Related Art

Miniaturization has been a trend for most current electronic products, and this trend will be obviously anticipated not only in mobile phones but also in wireless local area network (WLAN) systems, for example, systems based on bluetooth technology or IEEE 802.11 standard. For products operated with microwave (radio frequency and intermediate frequency), main electronic elements thereof include not only active RF ICs and RF modules but also a large number of passive elements, particularly surface acoustic wave (SAW) filters. Because of the contribution of active elements on integration technology, the total number of electronic elements within a product tends to be decreased. On the contrary, the total number of surface acoustic wave filters within a product has been increasing gradually. With the development of mobile phones having multiple functions, dual-band GSM mobile phones generally need about four (4) to five (5) RF surface acoustic wave filters while CDMA mobile phones having multiple bands and modules need more than five (5). Therefore, the surface acoustic wave filters must do some contributions to miniaturization so as to meet the market requirement and achieve the goal of miniaturization of electronic products.

A surface acoustic wave chip comprises interdigital transducers (IDT) generally formed of a patterned aluminum film and constructed as electrodes. According to frequency requirements, the line widths of the interdigital transducers need to be thinner as the operating frequency of the interdigital transducers get higher. For example, the line widths would be around 0.5 μm as the operating frequency is 1.7 to 1.9 GHz. In addition, the patterned aluminum film is generally less than 1 μm in thickness such that the functions of the surface acoustic wave chip will be easily changed as the IDT is contaminated by moisture or dust. Therefore, a hermetic package structure is absolutely necessary for surface acoustic wave chips or elements. As shown in FIG. 1, it depicts a conventional SAW chip package structure with a highly reliable hermetic seal.

Referring to FIG. 1, it shows a sectional view of a SAW chip package structure with a hermetic seal. The package structure 10 comprises a cavity 12, formed by a bottom board 14, side walls 16a, 16b, 16c and a lid board 18, for protecting a SAW chip 13. Generally, the bottom board 14 and the side walls 16a, 16b, 16c are made of ceramic materials, and the lid board 18 can be made of ceramic materials or metal materials. The upper surface of the bottom board 14 is applied with an adhesive 20 for bonding the SAW chip 13. The SAW chip 13 includes a piezoelectric substrate 13a, an interdigital transducer (IDT) 13b, and bonding pads 13c. The bonding pads 13c are electrically connected to internal bonding pads 24 through wires 22, and the internal bonding pads 24 are electrically connected with external bonding pads 26 such that the SAW chip 13 can be electrically connected to an external circuit (not shown). However, this package structure 10 will not be able to meet the requirements of electronic products in the future due to its large scale and high manufacturing cost.

In order to minimize the volume of a SAW chip package structure, U.S. Pat. No. 6,417,026 issued to Gotoh et al. discloses an acoustic wave device face-down mounted on a substrate, the scale of which has been reduced to less than half of that of the conventional SAW chip package structure.

As shown in FIG. 2a, it depicts a sectional view of a SAW chip package structure disclosed by Gotoh et al. A package structure 30 comprises a SAW chip 32 comprising a piezoelectric substrate 32a, an interdigital transducer (IDT) 32b, and bonding pads 32c. The bonding pads 32c have an insulating layer 34 formed thereon for enclosing the IDT 32b and parts of the pads 32c. A protection layer 36 is made to cover the insulating layer 34 so as to form a hermetic cavity 38 for protecting a main active surface 32d and the IDT 32b of the SAW chip 32. Referring to FIG. 2b, the bonding pads 32c are electrically connected to bump electrodes 40 respectively, and the bump electrodes 40 penetrate through the insulating layer 34 and the protection layer 36 so as to be electrically connected to circuit traces 44. After the bump electrodes 40 of the SAW chip 32 are connected to the bump electrodes of the substrate 42, the upper portion of the SAW chip 32 is sealed and protected with a buffer resin 46 for stress relaxation and electrical insulation, and an exterior resin 48 extended onto the circuit substrate for mechanical protection and enhancement of moisture resistance.

Although the scale of the package structure disclosed by Gotoh et al. has been greatly reduced, the process of forming the hermetic cavity 38 is still complicated as shown in FIG. 2b. The process includes several times in lithography, exposure, metal plating and chemical etching such that the manufacturing cost can still not be greatly reduced.

Accordingly, the present invention provides a package structure with a cavity for minimizing the scale of a SAW chip package structure and further reducing the manufacturing cost.

### SUMMARY OF THE INVENTION

It is an object of the present invention to provide a package structure with a cavity for minimizing the scale of a SAW chip package structure and reducing the manufacturing cost.

In order to achieve the above object, the present invention provides a package structure with a cavity, which comprises a chip, a multi-layer ceramic substrate, and an adhesive layer. The chip has a circuit disposed thereon and a plurality of first bonding pads disposed around the circuit. The multi-layer ceramic substrate has a cave formed thereon and a plurality of second bonding pads disposed around the cave, wherein the cave and the plurality of second bonding pads are corresponding to the circuit and the plurality of first bonding pads, respectively. The adhesive layer is applied to the surface of the substrate, with the cave and the second bonding pads exposed from the adhesive layer, for tightly bonding the chip and the multi-layer ceramic substrate together such that the circuit of the chip is corresponding to the cave of the multi-layer ceramic substrate so as to form a cavity.

### BRIEF DESCRIPTION OF THE DRAWINGS

Other objects, advantages, and novel features of the present invention will become more apparent from the following detailed description when taken in conjunction with the accompanying drawings.

FIG. 1 is a sectional view of a conventional SAW chip package structure with a hermetic seal.

FIG. 2a is a sectional view of another conventional SAW chip package structure mounted on a substrate wherein the package structure has a hermetic seal therein.

FIG. 2b is a sectional view of the conventional SAW chip package structure with a hermetic seal.

FIG. 3 is an exploded view of a package structure with a hermetic cavity in accordance with an embodiment of the present invention.

FIG. 4 is a top plan view of a multi-layer ceramic substrate with an adhesive layer applied thereon.

FIG. 5 is a sectional view of a package structure with a hermetic cavity in accordance with an embodiment of the present invention.

FIG. 6 is a sectional view of a package structure with a hermetic cavity in accordance with another embodiment of the present invention.

FIG. 7 is a perspective view of a multi-layer ceramic substrate with a hole punched on its first green sheets.

FIG. 8 is a sectional view of the multi-layer ceramic substrate shown in FIG. 7.

FIG. 9 is a perspective view of a whole piece of multi-layer ceramic substrate prior to a cutting process and before or posterior to a sintering process.

### DETAILED DESCRIPTION OF THE PREFERRED EMBODIMENT

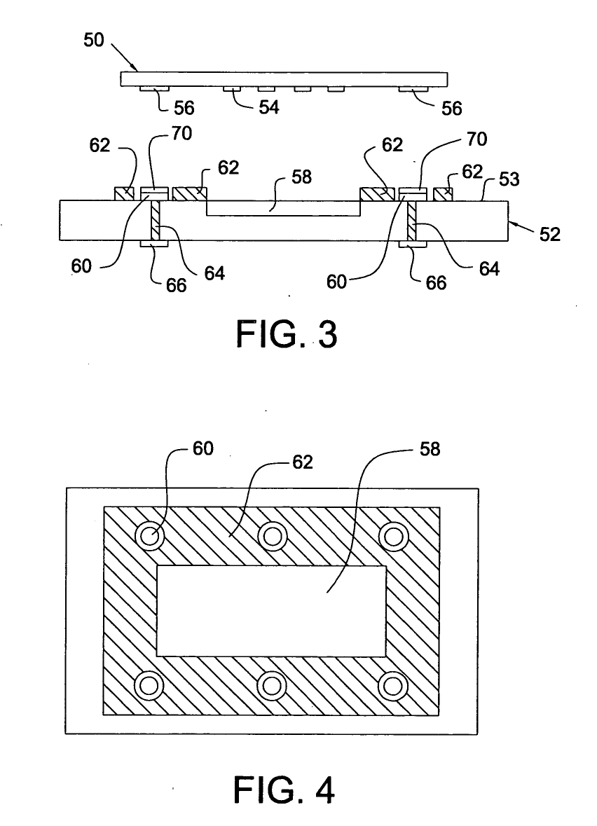

Now referring to FIG. 3, it is an exploded view of a package structure with a hermetic cavity in accordance with an embodiment of the present invention. It shows a chip 50 and a multi-layer ceramic substrate 52. The chip 50 further has a circuit 54 disposed thereon and a plurality of first bonding pads 56 disposed around the circuit 54 for being electrically connected to the circuit 54 and an external circuit (not shown). The surface 53 of the multi-layer ceramic substrate 52 has a cave 58 corresponding to the circuit 54 and a plurality of second bonding pads 60 which are disposed around the cave 58 and corresponding to the plurality of first bonding pads 56 of the chip 50. The surface 53 of the multi-layer ceramic substrate 52 is applied with an adhesive layer 62, such as an adhesive resin, with the cave 58, the second bonding pads 60, and the border of the surface 53 exposed from the adhesive layer 62. As shown in FIG. 4, it shows a plan view of the multi-layer ceramic substrate 52 with the adhesive layer 62 applied on the surface 53.

Referring to FIG. 3, the multi-layer ceramic substrate 52 comprises a plurality of via conductors 64 penetrating therethrough, wherein one ends of the via conductors 64 are respectively connected to the plurality of second bonding pads 60, and the other ends of the via conductors 64 are respectively connected to a plurality of external bonding pads 66 for being able to connect with an external circuit (not shown).

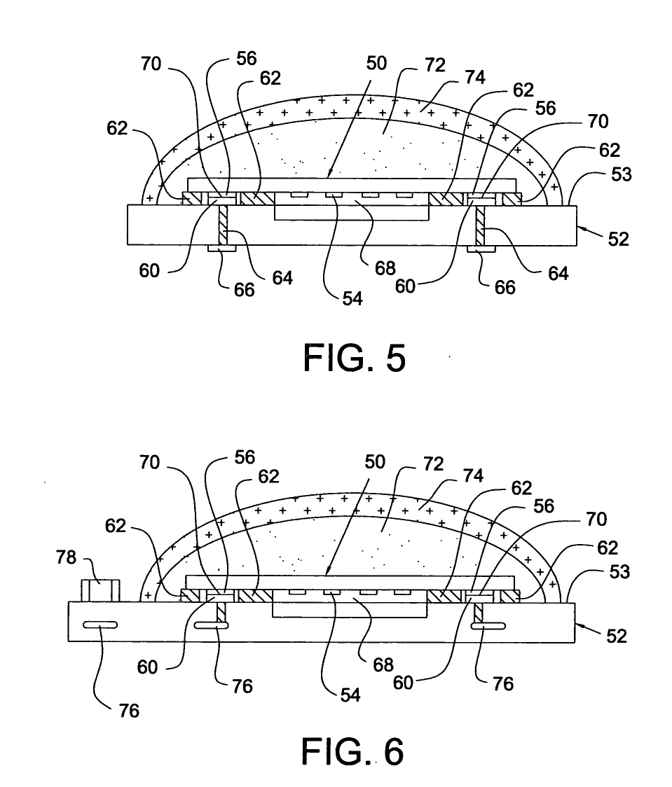

While the chip 50 is in contact with the multi-layer ceramic substrate 52 by the plurality of first bonding pads 56 respectively aligned with the plurality of second bonding pads 60, a pressure is applied on respective outer sides of the chip 50 and the substrate 52 so as to tightly bond the chip 50 and the substrate 52 together by the adhesive layer 62, such that the circuit 54 of the chip is corresponding to the cave 58 of the multi-layer ceramic substrate 52 so as to form a cavity 68 as shown in FIG. 5.

Each second bonding pad 60 has a gold layer 70 formed thereon so as to facilitate electrical connection between the second bonding pad 60 and the first bonding pad 56 by the gold layer 70. After the chip 50 is bonded to the multi-layer ceramic substrate 52 by the adhesive layer 62, the plurality of first bonding pads 56 are electrically connected to the plurality of second bonding pads 60 by an ultrasonic bonding process so as to form a reliable and strengthened connections therebetween. In addition, the upper portion of the SAW chip 50 and part of the multi-layer ceramic substrate 52 can be sealed and protected with a buffer resin 72, preferably silicone resin, for stress relaxation and electrical insulation, and the buffer resin 72 can be further sealed and protected with an exterior resin 74, preferably epoxy resin, for mechanical protection and enhancement of moisture resistance.

It should be noted that the plurality of via conductors 64 electrically connected to the second bonding pads 60 of the multi-layer ceramic substrate 52 can also be connected to other circuits by inner conductors 76 within the multi-layer ceramic substrate 52. For example, one of the via conductors 64 is electrically connected to a device 78 disposed on the multi-layer ceramic substrate 52 as shown in FIG. 6.

According to the embodiment of present invention, the chip is a SAW chip and the circuit is an interdigital transducer (IDT). It should be understood that the package structure with a cavity can also be applied to other kind of chips having circuits thereon such as crystal chip, micro electromechanical system (MEMS) chip, semiconductor chip, and optical chip. The multi-layer ceramic substrate according to the present invention can be made of materials such as AlN, low-temperature co-fired ceramic (LTCC), multi-layer co-fired ceramic (MLCC), AL₂O₃, and polymeric materials in the embodiments of the present invention.

According to the package structure of the present invention, a method for making a package structure with a cavity comprises following steps: (a) providing a chip having a circuit disposed thereon and a plurality of first bonding pads disposed around the circuit wherein the circuit is electrically connected to a external circuit by the plurality of first bonding pads, and the chip can be SAW chip, semiconductor chip, or optical chip; (b) providing a multi-layer ceramic substrate having a cave formed thereon and a plurality of second bonding pads disposed around the cave, wherein the cave and the plurality of second bonding pads are respectively corresponding to the circuit and the plurality of first bonding pads; (c) applying an adhesive layer to the surface of the substrate, with the cave and the second bonding pads exposed from the adhesive layer, for bonding the chip and the multi-layer ceramic substrate together; (d) tightly bonding the chip and the multi-layer ceramic substrate together such that the circuit of the chip is corresponding to the cave of the multi-layer ceramic substrate so as to form a cavity, and then electrically connecting the plurality of first bonding pads with the plurality of second bonding pads by an ultrasonic bonding process, wherein the plurality of first bonding pads and the plurality of second bonding pads are bonded together with preferably a gold layer as its interface. In step (b), the multi-layer ceramic substrate is punched a hole on at least one green sheet thereof before a sintering process so as to form the cave thereon after the sintering process. Preferably, the multi-layer ceramic substrate can be made of materials such as AlN, low-temperature co-fired ceramic (LTCC), multi-layer co-fired ceramic (MLCC), AL₂O₃, and polymeric materials.

The above-mentioned method further comprises the step: sealing the upper portion of the chip and the multi-layer ceramic substrate with a buffer resin, preferably silicone resin, for stress relaxation and electrical insulation; and sealing the buffer resin with an exterior resin, preferably epoxy resin, for mechanical protection and enhancement of moisture resistance.

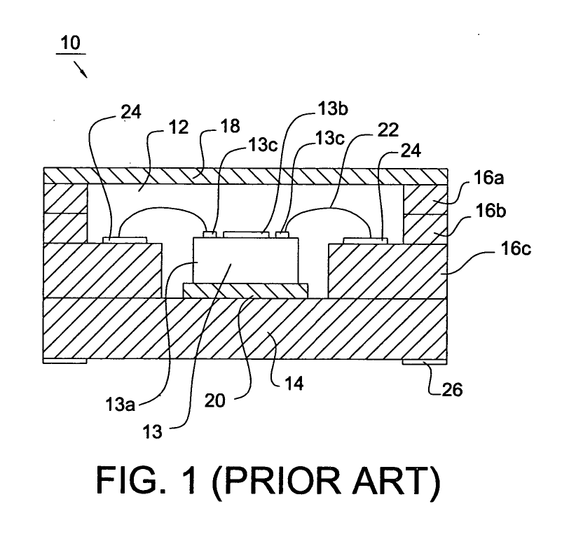

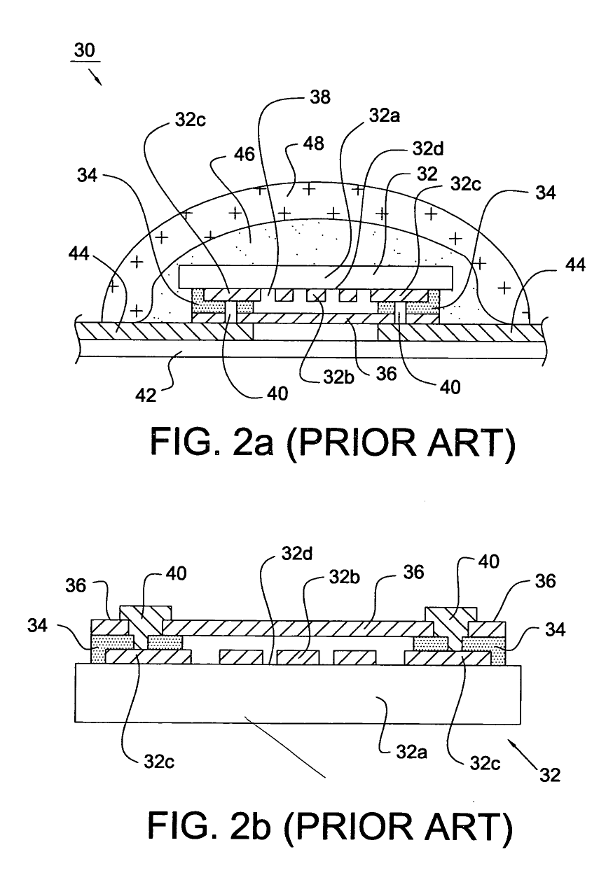

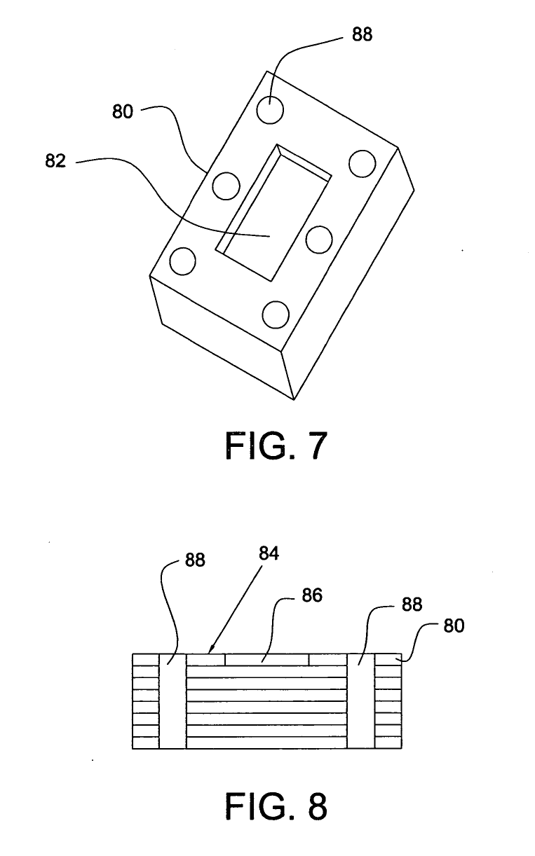

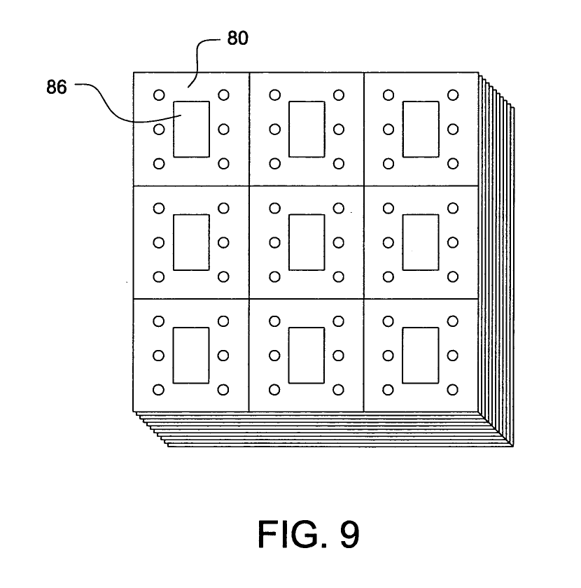

As shown in FIGS. 1, 2a and 2b, the complicated structure of the conventional SAW chip package only provides the SAW, having a circuit thereon, with a hermetic cavity so as to prevent the circuit from being affected by environmental moisture or dust. In fact, the film thickness of the IDT is less than 1 μm. The present invention utilizes multi-layer ceramic (MLC), particularly low-temperature co-fired ceramic (LTCC), as the substrate for the package structure. Generally, a multi-layer ceramic green sheet can be made around 50 μm in minimum thickness with conventional techniques. For Non-shrinkage LTCC techniques, such a thickness of 50 μm will shrink to at least 25 μm after a sintering process. In addition, a substrate must be at least 300 μm in thickness so as to meet the basic requirement of strength. For a multi-layer ceramic green sheet with a thickness of 100 μm, six green sheets are required so as possibly to obtain a substrate with a thickness of 300 μm after the sintering process. According to this fact, the cave of the package structure of the present invention can be easily formed only by punching a hole (as shown in FIGS. 7, 8, and 9), which matches a designed IDT pattern, on the first green sheet of a multi-layer ceramic substrate. It should be noted that via conductors or inner conductors could be accomplished on the multi-layer ceramic substrate when they are required. As shown in FIG. 8 and FIG. 9, the present invention provides a simplest design of via conductor on a substrate such that the SAW chip can be packaged as a chip-size scale package on the substrate by a surface mounted technology.

According to one aspect of the present invention, the method of forming a cave on a multi-layer ceramic substrate is mainly to punch a hole 82 on at least first one green sheet 80 or first several from the top of several aligned green sheets before a sintering process for these green sheets wherein the shape of the hole 82 can be square, rectangular, oval, and any other shape which matches the shape of a chip as shown in FIG. 7, and then laminate these green sheets, which may include the green sheets with the hole thereon and green sheets without the hole thereon, so as to sinter these green sheets to form a multi-layer ceramic substrate 84 with a cave 86 formed thereon as shown in FIG. 8. It should be noted that the multi-layer ceramic substrate 84 has a plurality of via conductors 88 formed thereon for being as electrical paths. As shown in FIG. 9, it shows a perspective view of a whole piece of multi-layer ceramic substrate prior to a cutting process and before or posterior to a sintering process.

The present invention utilizes a multi-layer ceramic (MLC) technology, particularly a low-temperature co-fired ceramic (LTCC) technology, to accomplish a minimized package of a SAW chip. The substrate formed in according to the present invention is also the substrate of the chip. Therefore, the new technique according to the present invention not only can accomplish the chip-size package but also can broaden the application of chips as well as decrease the manufacturing cost.

While the foregoing descriptions and drawings represent the preferred embodiments of the present invention, it should be understood that various additions, modifications and substitutions may be made therein without departing from the spirit and scope of the principles of the present invention as defined in the accompanying claims. One skilled in the art will appreciate that the invention may be used with many modifications of form, structure, arrangement, proportions, materials, elements, and components. The presently disclosed embodiments are therefore to be considered in all respects as illustrative and not restrictive, and the scope of the invention should be defined by the appended claims and their legal equivalents, not limited to the foregoing descriptions.

What is claimed is:

1. A package structure with a cavity comprising:
a chip having a circuit disposed thereon and a plurality of first bonding pads disposed around the circuit, and the first bonding pads electrically connected to the circuit and an external circuit;
a multi-layer ceramic substrate having a cave formed thereon and a plurality of second bonding pads disposed around the cave, wherein the cave and the plurality of second bonding pads are corresponding to the circuit and the plurality of first bonding pads, respectively; and
an adhesive layer being substantially applied to the surface of the substrate, with the cave and the second bonding pads exposed from the adhesive layer, for tightly bonding the chip and the multi-layer ceramic substrate together such that the circuit of the chip is corresponding to the cave of the multi-layer ceramic substrate so as to form a cavity;
wherein the plurality of second bonding pads are respectively connected to a plurality of via conductors on the multi-layer ceramic substrate so as to connect with an external circuit.

2. The package structure with a cavity as claimed in claim 1, wherein the chip is a SAW chip, and the circuit is an interdigital transducer (IDT).

3. The package structure with a cavity as claimed in claim 1, wherein the chip is a semiconductor chip.

4. The package structure with a cavity as claimed in claim 1, wherein the chip is an optical chip.

5. The package structure with a cavity as claimed in claim 1, wherein the chip is a crystal chip.

6. The package structure with a cavity as claimed in claim 1, wherein the chip is a MEMS chip.

7. The package structure with a cavity as claimed in claim 1, wherein the material of the multi-layer ceramic substrate is selected from a group of AlN, low-temperature co-fired ceramic (LTCC), multi-layer co-fired ceramic (MLCC), AL₂O₃, and polymeric materials.

8. The package structure with a cavity as claimed in claim 1, wherein the plurality of first bonding pads are electrically connected to the plurality of second bonding pads by a gold layer.

9. The package structure with a cavity as claimed in claim 1 further comprising a buffer resin sealing and protecting the upper portion of the chip and the multi-layer ceramic substrate for stress relaxation and electrical insulation.

10. The package structure with a cavity as claimed in claim 9 further comprising a epoxy resin sealing and protecting the buffer resin for mechanical protection and enhancement of moisture resistance.
